(19) United States
(12) Patent Application Publication
(10) Pub. No.: US 2024/0070506 A1
(43) Pub. Date: Feb. 29, 2024

(54) CRYOGENIC FILTER MODULES FOR SCALABLE QUANTUM COMPUTING ARCHITECTURES

(71) Applicant: International Business Machines Corporation, Armonk, NY (US)

(72) Inventors: Devin Underwood, New York, NY (US); Timothy Phung, Milpitas, CA (US); Muir Kumph, Croton on Hudson, NY (US)

(21) Appl. No.: 17/822,499

(22) Filed: Aug. 26, 2022

(51) Int. Cl. G06N 10/40

(52) U.S. Cl. CPC G06N 10/40

(57) ABSTRACT

One or more systems, devices, and/or methods of use provided herein relate to signal filters for scalable quantum computing architectures. According to one embodiment, a device can comprise a circuit board comprising a plurality of layers, wherein various ones of the plurality of layers comprises a different absorptive material, and a plurality of signal lines that pass through the circuit board, wherein a first layer of the circuit board is comprised of a first material that filters a first signal line that traverses through at least the first layer of the plurality of layers.

### BACKGROUND

The subject disclosure relates signal filters and more specifically, to cryogenic filter modules for scalable quantum computing architectures.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, and apparatuses are described that facilitate operation, design, and/or manufacture cryogenic filter modules for scalable quantum computing architectures.

According to an embodiment, a system can comprise a device, wherein the device can comprise a circuit board comprising a plurality of layers, wherein various ones of the plurality of layers comprises a different absorptive material, and a plurality of signal lines that pass through the circuit board, wherein a first layer of the circuit board is comprised of a first material that filters a first signal line that traverses through at least the first layer of the plurality of layers. An advantage of such a device is that plurality of layers can serve as low pass filters at frequencies wherein reactive components break down due to self-resonances.

In some embodiments of the above described device, a second layer of the circuit board can comprise a second material that filters the first signal line that traverses through at least the first layer and the second layer of the plurality of layers. An advantage of such a device is that absorptive materials of the plurality of layers can be selected based on an intended filtering of the first transmission line.

According to an embodiment, a system can comprise a device, wherein the device can comprise a circuit board comprising a plurality of layers, wherein various ones of the plurality of layers comprise one or more different absorptive materials, and a plurality of signal lines that pass through the circuit board, wherein a first layer of the circuit board is comprised of a first material and a second material, wherein a first signal line traverses through at least the first layer and wherein the first signal line comprises a first width that traverses through the first material and a second width that traverses through the second material. An advantage of such a system is that first and second materials can serve as low pass filters for the signal line.

In some embodiments of the above described system, the system can further comprise a fabricated chip coupled to the first signal line. An advantage of such a system is that the fabricated chip enables additional filtering and/or attenuating.

According to an embodiment, a method can comprise transmitting a signal, and filtering the signal employing a filter circuit board, wherein the filter circuit board comprises a plurality of layers, wherein various ones of the plurality of layers comprise a different absorptive material, and a signal line that traverses through at least a first layer of the plurality of layers, wherein the signal line carries the signal and wherein the first layer is comprised of a first material that filters the signal line. An advantage of such a method is that the plurality of layers enable low pass filtering at frequencies wherein reactive components break down due to self-resonances.

In some embodiments, the above described method can further comprise attenuating the signal employing an attenuator coupled to the filter circuit board. An advantage of such a method is that it can improve coherence of the signal.

According to an embodiment, a system can comprise a device, wherein the device comprises a circuit board comprising a non-absorptive layer and a plurality of absorptive layers, wherein various one of the plurality of absorptive layers comprises a different absorptive material, and a plurality of signal lines that pass through the circuit board, wherein a first layer of the circuit board is comprised of a first material that filters a first signal line that travers through at least the first layer of the plurality of absorptive layers. An advantage of such a device is that plurality of absorptive layers can serve as low pass filters at frequencies wherein reactive components break down due to self-resonances.

According to an embodiment, a method can comprise determining a desired frequency response of a filter, selecting one or more absorptive materials based on the desired frequency response, selecting one or more signal line traversal lengths for the one or more absorptive materials, and assembling a circuit board comprising a plurality of layers, wherein various ones of the plurality of layers comprise different absorptive materials of the one or more absorptive materials selected based on the desired frequency response. An advantage of such a method is that filters can be designed to provide an intended filter response.

Various other details of various embodiments described herein are presented in the following clauses.

CLAUSE 1: A system comprising: a device comprising: a circuit board comprising a plurality of layers, wherein various ones of the plurality of layers comprises a different absorptive material; and a plurality of signal lines that pass through the circuit board, wherein a first layer of the circuit board is comprised of a first material configured to filter a first signal line that traverses through at least the first layer of the plurality of layers. An advantage of such a device is that plurality of layers can serve as low pass filters at frequencies wherein reactive components break down due to self-resonances.

CLAUSE 2: The system of any preceding clause specified in the Summary, wherein a second layer of the circuit board is comprised of a second material configured to filter the first signal line that traverses through at least the first layer and the second layer of the plurality of layers.

CLAUSE 3: The system of any preceding clause specified in the Summary, wherein the first signal line comprises a first length that traverses through the first layer and a second length that traverses through the second layer.

CLAUSE 4: The system of any preceding clause specified in the Summary, further comprising one or more fabricated chips joined to the circuit board.

CLAUSE 5: The system of any preceding clause specified in the Summary, wherein the one or more fabricated chips comprise at least one of an attenuator or a reactive low pass filter.

CLAUSE 6: The system of any preceding clause specified in the Summary, wherein at least one layer of the plurality of layers comprises at least one of an attenuator or a reactive low pass filter.

CLAUSE 7: The system of any preceding clause specified in the Summary, wherein the first layer is formed of an absorptive material, wherein the absorptive material is configured to provide a low pass filter function, and wherein the second layer is formed of a second absorptive material, wherein the second absorptive material is configured to provide a second low pass filter function.

CLAUSE 8: The system of any preceding clause specified in the Summary, wherein a type of the first signal line is one of a microstrip or a stripline.

CLAUSE 9: The system of any preceding clause specified in the Summary, further comprising a quantum computing system comprising the device.

CLAUSE 10: A system comprising: a device comprising: a circuit board comprising a plurality of layers, wherein various ones of the plurality of layers comprise one or more different absorptive materials; and a plurality of signal lines that pass through the circuit board, wherein a first layer of the circuit board is comprised of a first material and a second material, wherein a first signal line traverses through at least the first layer and wherein the first signal line comprises a first width that traverses through the first material and a second width that traverses through the second material. An advantage of such a method is that filters can be designed to provide an intended filter response.

CLAUSE 11: The system of any preceding clause specified in the Summary, further comprising a fabricated chip coupled to the first signal line.

CLAUSE 12: The system of any preceding clause specified in the Summary, wherein the fabricated chip comprises at least one of an attenuator or a reactive low pass filter.

CLAUSE 13: The system of any preceding clause specified in the Summary, wherein the first signal line traverses though at least the first layer and a second layer.

CLAUSE 14: The system of any preceding clause specified in the Summary, wherein the second layer comprises at least one of an attenuator or a reactive low pass filter.

CLAUSE 15: The system of any preceding clause specified in the Summary, further comprising a second fabricated chip coupled to a second signal line, wherein the second signal line traverses through at least a third layer of the plurality of layers.

CLAUSE 16: The system of any preceding clause specified in the Summary, wherein the second fabricated chip comprises at least one of an attenuator or a reactive low pass filter.

CLAUSE 17: A method comprising: transmitting a signal; and filtering the signal employing a filter circuit board, wherein the filter circuit board comprises: a plurality of layers, wherein various ones of the plurality of layers comprise a different absorptive material; and a signal line that traverses through at least a first layer of the plurality of layers, wherein the signal line is configured to carry the signal and wherein the first layer is comprised of a first material configured to filter the signal line.

CLAUSE 18: The method of any preceding clause specified in the Summary, wherein the signal line traverses through at least the first layer and a second layer of the plurality of layers, wherein the second layer is comprised of a second material configured to filter the signal line.

CLAUSE 19: The method of any preceding clause specified in the Summary, further comprising filtering the signal employing a reactive low pass filter coupled to the filter circuit board.

CLAUSE 20: The method of any preceding clause specified in the Summary, further comprising attenuating the signal employing an attenuator coupled to the filter circuit board.

CLAUSE 21: The method of any preceding clause specified in the Summary, wherein the signal comprises a control signal for a qubit in a quantum computer.

CLAUSE 22: The method of any preceding clause specified in the Summary, wherein the signal comprises a readout request signal for a qubit in a quantum computer.

CLAUSE 23: A system comprising: a device comprising: a circuit board comprising a non-absorptive layer and a plurality of absorptive layers, wherein various one of the plurality of absorptive layers comprises a different absorptive material; and a plurality of signal lines that pass through the circuit board, wherein a first layer of the circuit board is comprised of a first material configured to filter a first signal line that travers through at least the first layer of the plurality of absorptive layers.

CLAUSE 24: The system of any preceding clause specified in the Summary, wherein a second signal line traverses through the non-absorptive layer.

CLAUSE 25: A method comprising: determining a desired frequency response of a filter; selecting one or more absorptive materials based on the desired frequency response; selecting one or more signal line traversal lengths for the one or more absorptive materials; and assembling a circuit board comprising a plurality of layers, wherein various ones of the plurality of layers comprise different absorptive materials of the one or more absorptive materials selected based on the desired frequency response.

### DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates a diagram of an example, non-limiting filtering module in accordance with one or more embodiments described herein.

FIG. 2 illustrates a cross-section diagram of an example, non-limiting filter module with a fast flux transmission line in accordance with one or more embodiments described herein.

FIG. 3 illustrates a second cross-section diagram of an example, non-limiting filter module with a radio frequency control line in accordance with one or more embodiments described herein.

FIG. 4 illustrates a third cross-section diagram of an example, non-limiting filter module with a readout line in accordance with one or more embodiments described herein.

FIG. 5 illustrates a graph comparing the absorptive properties of various absorptive materials with filter functions in accordance with one or more embodiments described herein.

FIG. 6 illustrates an algorithm for designing a plurality of absorptive layers in accordance with one or more embodiments described herein.

FIGS. 7A and 7B illustrate graphs showing the filtering of one or more filter modules in accordance with one or more embodiments described herein.

FIG. 8A illustrates a top-down view of a tapered signal line in a filter module in accordance with one or more embodiments described herein.

FIG. 8B illustrates an alternate view of a tapered signal line in a filter module in accordance with one or more embodiments, described herein.

FIG. 9 illustrates a diagram of a non-limiting filtering module in accordance with one or more embodiments described herein.

FIG. 10 illustrates a graph showing the filtering of two filter modules in accordance with one or more embodiments described herein.

FIG. 11 illustrates a flow diagram of an example, non-limiting method for designing a filter module in accordance with one or more embodiments described herein.

FIG. 12 illustrates a flow diagram of an example, non-limiting method of filtering an electromagnetic signal in accordance with one or more embodiments described herein.

FIG. 13 illustrates a flow diagram of an example, non-limiting method of filtering an electromagnetic signal in accordance with one or more embodiments described herein.

FIG. 14 illustrates a flow diagram of an example, non-limiting method for designing a filter module in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

Quantum computing is generally the use of quantum-mechanical phenomena to perform computing and information processing functions. Quantum computing can be viewed in contrast to classical computing, which generally operates on binary values with transistors. That is, while classical computers can operate on bit values that are either 0 or 1, quantum computers operate on quantum bits (qubits) that comprise superpositions of both 0 and 1, which can entangle multiple quantum bits and can use interference. This quantum superposition allows quantum systems to store and represent large data sets that are difficult to represent classically. Quantum computing has the potential to solve problems that, due to computational complexity, cannot be solved or can only be solved slowly on a classical computer. In many forms of quantum computers, the qubits within the quantum computer are operated through the use of radio frequency waves. As such, quantum computer can receive an instruction from a classical input, and then perform the instruction through the use of waveforms to operate the qubits within the quantum computer.

Scalable quantum computing architectures call for high density signal delivery for different types of waveform signals. For example, qubit and readout pulse on input, fast flux pulses on input, and readout pulses on output have different unique filtering and thermalization demands in order to optimize qubit performance. Accordingly, filters for different types of signals call for specific frequencies and roll-offs to minimize signal degradation, especially in baseband applications. Designing a filter with a desired roll-off and cut-off frequency is challenging with absorptive materials, which have their own characteristic roll-offs. Accordingly, the disclosed subject matter can employ various techniques to realize a modular architecture for passively filtering noise, attenuating noise, and thermalizing signals as they pass between temperatures.

Given the problems described above relating to filtering of signal for operation of quantum computers, the present disclosure can be implemented to produce a solution to these problems in the form of devices, systems, apparatuses, and/or methods that can comprise: a circuit board comprising a plurality of layers, wherein various ones of the plurality of layers comprises a different absorptive material, and a plurality of signal lines that pass through the circuit board, wherein a first layer of the circuit board is comprised of a first material that filters a first signal line that traverses through at least the first layer of the plurality of layers. An advantage of such devices, systems, apparatuses, and/or methods is that plurality of layers can serve as low pass filters at frequencies wherein reactive components break down due to self-resonances. For example, each layer of the plurality of absorptive layers which a signal line traverses through can contribute to the filtering of the signal line, thereby enabling desired filtering of the signal line.

One or more embodiments are now described with reference to the drawings, where like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Further, it will be appreciated that the embodiments depicted in one or more figures described herein are for illustration only, and as such, the architecture of embodiments is not limited to the systems, devices and/or components depicted therein, nor to any particular order, connection and/or coupling of systems, devices and/or components depicted therein.

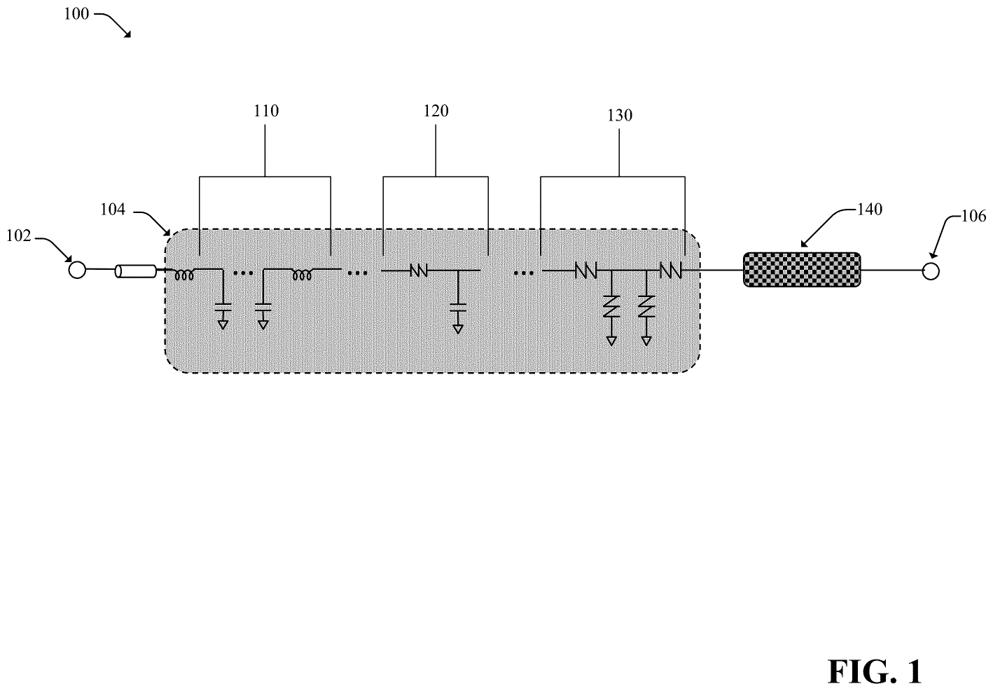

Turning now to the drawings, FIG. 1 illustrates a diagram of an example, non-limiting filter thermalization module 100 in accordance with one or more embodiments described herein.

As shown, filter thermalization module 100 can comprise connection 102 (e.g., an ardent), filter chip 104, absorptive filter 140, and second connection 106. In an embodiment, connection 102 can bring signals on to filter thermalization module 100. The signals can then pass through filter chip 104. In an embodiment, filter chip 104 can comprise resonant filters 110, passive filters 120, and attenuators 130. In another embodiment, filter chip 104 can additionally comprise a reactive low pass filter. The signals can then pass from filter chip 104 through absorptive filter 140 and second connection 106 can bring the filtered and attenuated signals off the board.

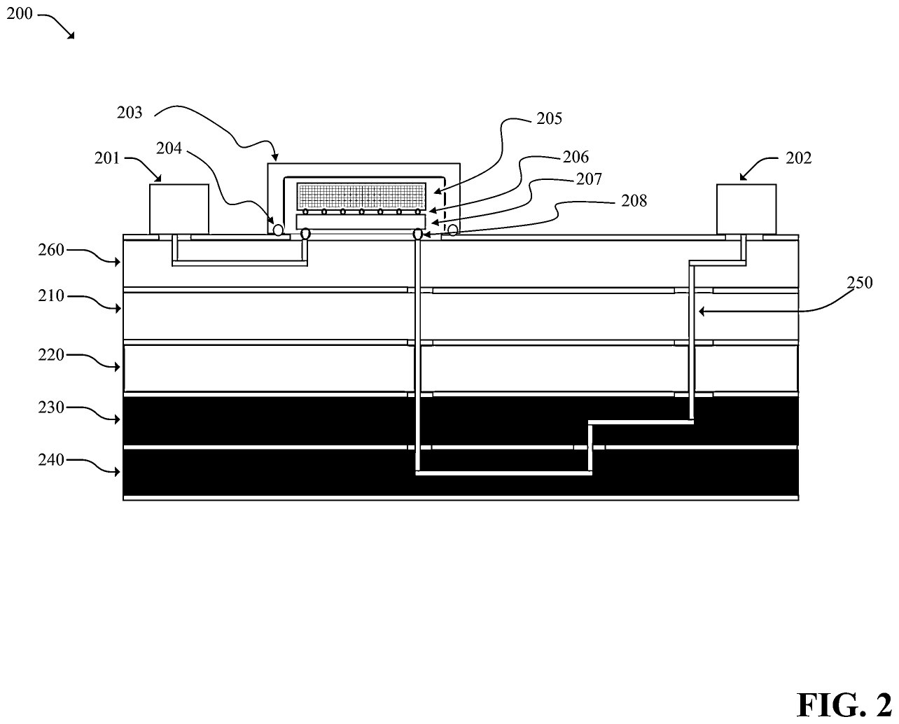

FIG. 2 illustrates a cross-section diagram of an example, non-limiting filter module 200 with a fast flux transmission line (e.g., Z control transmission line) in accordance with one or more embodiments described herein. As shown, filter module 200 can comprise first connection 201, second connection 202, chip shielding 203, filtering chip 205, ball grid 206, interposer 207, bump bond 208, signal line 250, absorptive layer 240, absorptive layer 230, absorptive layer 220, absorptive layer 210 and non-absorptive layer 260. In an embodiment, absorptive layers 210-240 can comprise absorptive materials that filter out high frequency radiation. In an embodiment, the absorptive materials can comprise materials such as black-body absorbers. In one or more embodiments, absorptive materials can be selected that provide different amounts of filtering and roll-offs. As such, different forms of absorptive materials can be selected depending on the called for filtering and roll-off. For example, layer 240 can comprise a first type of absorptive material, layer 230 can comprise a second type of absorptive material, layer 220 can comprise a third type of absorptive material, and layer 210 can comprise a fourth type of absorptive material. In an embodiment an absorptive material that is lossy (e.g., dissipates electrical energy) and/or magnetically loaded (e.g., magnetically absorbent) can be utilized. In an embodiment, layers 210-240 can be layered according to increasing absorption in descending layers. For example, layer 240 can be more absorptive than layer 230, and layer 230 can be more absorptive than layer 220. In an additional embodiment, layers 210-240 can be layered according to decreasing absorption in descending layers. For example, layer 240 can be less absorptive than layer 230, and layer 230 can be less absorptive than layer 220. In an embodiment, the absorptive materials can comprise materials such as polyurethane foams, silicon rubber, carbon, or materials formed through laminate manufacture processes. In an embodiment, the absorptive materials can comprise one or more forms of Eccosorb®. In an embodiment, signal line 250 can traverse through one or more layers of layers 210-240 based on the called for filtering of signal line 250. For example, as shown, signal line 250 traverses horizontally through layers 240 and layers 230 but does not traverse horizontally through layers 210 or 220. Accordingly, signal line 250 is filtered by layers 240 and 230 and is not filtered by layers 220 and 210. It should be appreciated that signal line 250 can traverse through different layers for different lengths. For example, as shown, signal line 250 traverses through layer 240 for a greater length than through layer 230. As the length of a layer signal line 250 passes through impacts the filtering of signal line 250, different traversal lengths can be selected to realize different amounts of filtering and roll-offs. It should be appreciated that signal line 250 can comprise any form of microwave or radio frequency signal medium, such as but not limited to a microstrip or a stripline. It should also be appreciated that layers within the plurality of layers can comprise additional elements beyond absorptive materials. For example, one or more layers of the plurality of layers can comprise elements such as attenuators or reactive low pass filters.

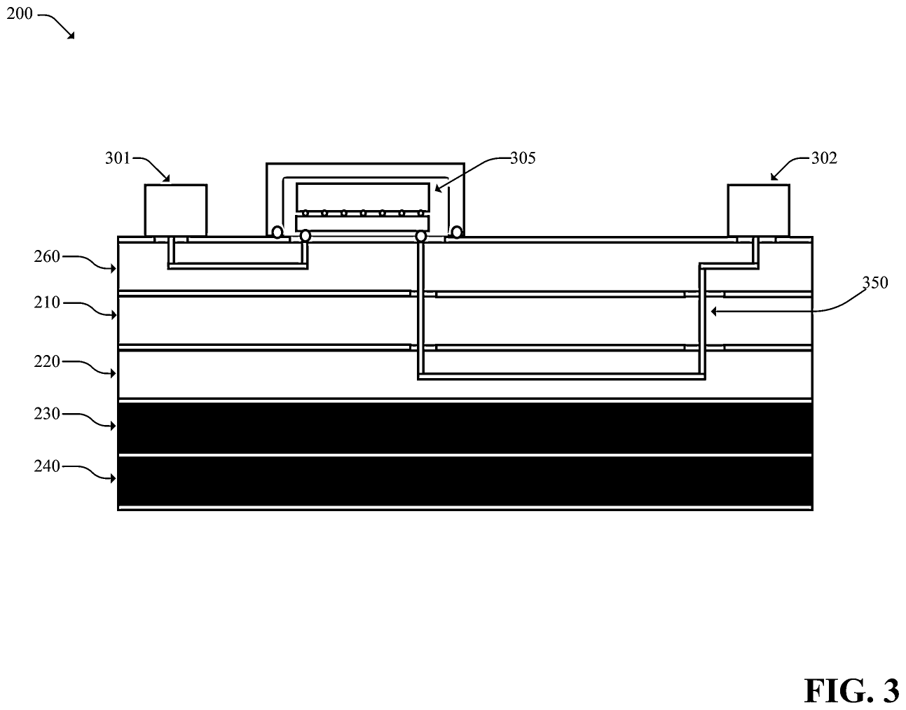

FIG. 3 illustrates a second cross-section diagram of an example, non-limiting filter module 200 with a radio frequency control line (e.g., XY control transmission line) in accordance with one or more embodiments described herein. Repetitive description of like elements and/or processes employed in respective embodiments is omitted for sake of brevity. In an embodiment, filter module 200 can comprise a plurality of signal lines. For example, as shown in FIG. 3, filter module 200 can comprise second signal line 350. As shown, second signal line 350 traverses horizontally through layer 220, but does not traverse horizontally through layer 210, layer 230, or layer 240. Accordingly, signal line 350 is filtered by layer 220, but not by layer 210, layer 230, or layer 240.

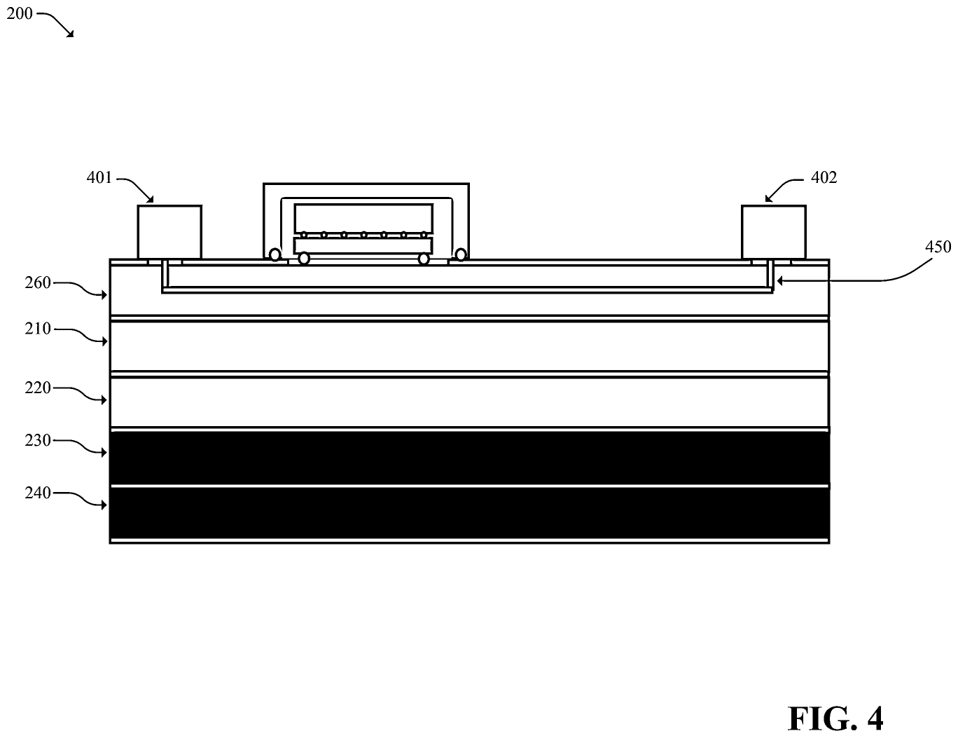

FIG. 4 illustrates a third cross-section diagram of an example, non-limiting filter module 200 with a readout line in accordance with one or more embodiments described herein. Repetitive description of like elements and/or processes employed in respective embodiments is omitted for sake of brevity. In an embodiment, filter module 200 can additionally comprise a third signal line 450 which is a read outline intended to read out the state of one or more qubits in a quantum computer. As read out lines often do not utilize filtering, third signal line 450 does not pass through a filter chip and does not traverse through any of layers 210, 220, 230 or 240. Rather signal line 450 as shown traverses through non-absorptive layer 260, which does not provide any filtering to third signal line 450. It should be appreciated in an embodiment, the filter thermalization modules described herein can comprise any number of absorptive layers and/or any number of signal lines. In another embodiment, a signal line can traverse through any number of absorptive layers. For example, a fourth signal line (not shown) can traverse through layer 210, layer 220, layer 230 and layer 240, or any combination of layers. It should also be appreciated that a signal line can traverse through any layer for any distance or length.

In an embodiment, various different forms and/or types of absorptive materials can be utilized. For example, different absorptive materials can have different properties, such as, magnetic permeability (e.g., the change in a magnetic field inside a material), magnetic loss tangent (e.g., the amount of magnetic power lost in a material compared to the amount of magnetic power stored in the material), dielectric loss tangent (e.g., a measure of dissipation of electrical energy passing through a material), attenuation per unit length (e.g., the amount of attenuation provided by a specific length of a material) and other properties. Accordingly, different absorptive materials or absorptive material types can provide different filtering functions. In an embodiment, an absorptive material that has a magnetic permeability in the range of 1.1-4.5 for a 1 GHz signal can be utilized. In an embodiment, an absorptive material that has a magnetic loss tangent in the range of 0-0.8 for a 1 GHz signal can be utilized. In an embodiment, an absorptive material that has a dielectric loss tangent in the range of 0.04-0.07 for a 1 GHz signal can be utilized. In an embodiment, an absorptive material that has an attenuation per unit length in the range of 0.09-27 dB per centimeter can be used. It should be appreciated that an absorptive material can have different properties, depending on the frequency of the signal passed through the absorptive material. For example, a material may have a different attenuation per unit length values for 1 GHz and 2 GHz signals respectively. In an embodiment, a filter can comprise a first absorptive material that has a magnetic permeability of 1.4 for a 1 GHz signal, a magnetic loss tangent of 0.02 for a 1 GHz signal, a dielectric loss tangent of 0.04 for a 1 GHz signal, and an attenuation per unit length of 0.16 dB per centimeter. The filter can further comprise a second absorptive material that has a magnetic permeability of 4.1 for a 1 GHz signal, a magnetic loss tangent of 0.20 for a 1 GHz signal, a dielectric loss tangent of 0.09 for a 1 GHz signal, and an attenuation per unit length of 2.8 dB per centimeter.

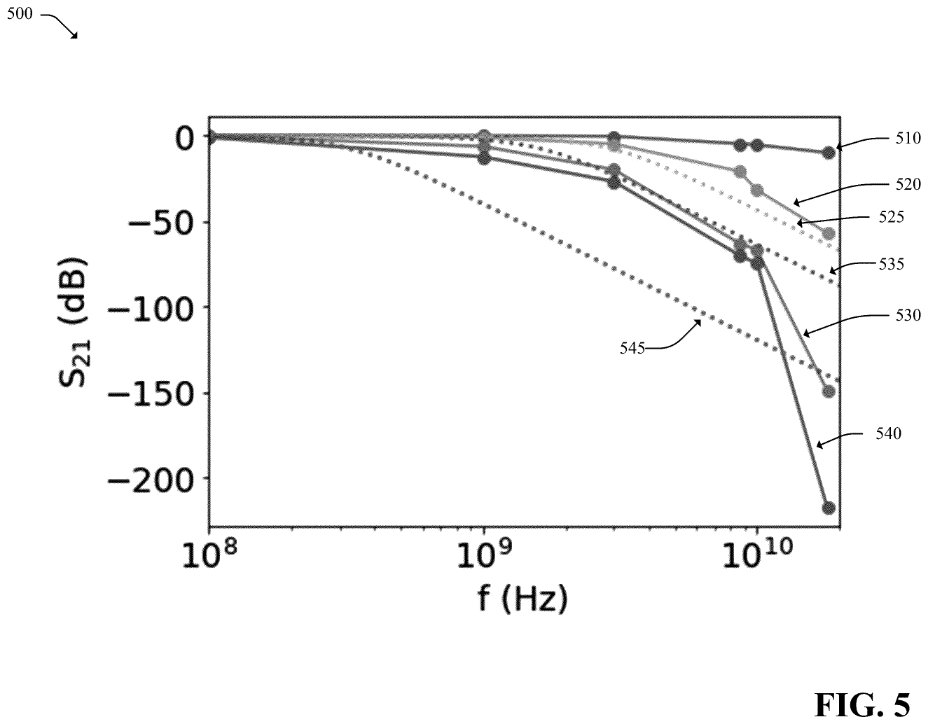

FIG. 5 illustrates a graph 500 comparing the absorptive properties of various absorptive material types with Bessel Thompson filters in accordance with one or more embodiments described herein. Repetitive description of like elements and/or processes employed in respective embodiments is omitted for sake of brevity.

The y-axis of graph 500 illustrates absorption (measured in dB) and the x-axis represents frequency of a signal (measured in Hz). Accordingly, graph 500 illustrates absorption plotted as a function of frequency for a signal line traversing 1 cm through different varieties of absorptive materials. Line 510, shown as solid blue, represents a first absorptive material Line 520, shown as solid orange, represents a second absorptive material type. Line 530, shown as solid green, represents a third absorptive material type. Line 540, shown as solid red, represents a fourth absorptive material. Line 525, shown as dotted orange, represents a Bessel Thompson filter f_{-3 dB}=2 GHz. Line 535, shown as dotted green, represents a Bessel Thompson filter f_{-3 dB}=1 GHz. Line 545, shown as dotted red, represents a Bessel Thompson filter f_{-3 dB}=200 MHz. As shown, a single type of absorptive material may not provide an intended amount of filtering on its own in some cases, illustrated by the difference between the solid and dotted lines. Accordingly, as described in greater detail below, multiple types of absorptive materials and/or different traversal lengths can be utilized in order to realize an intended amount of filtering.

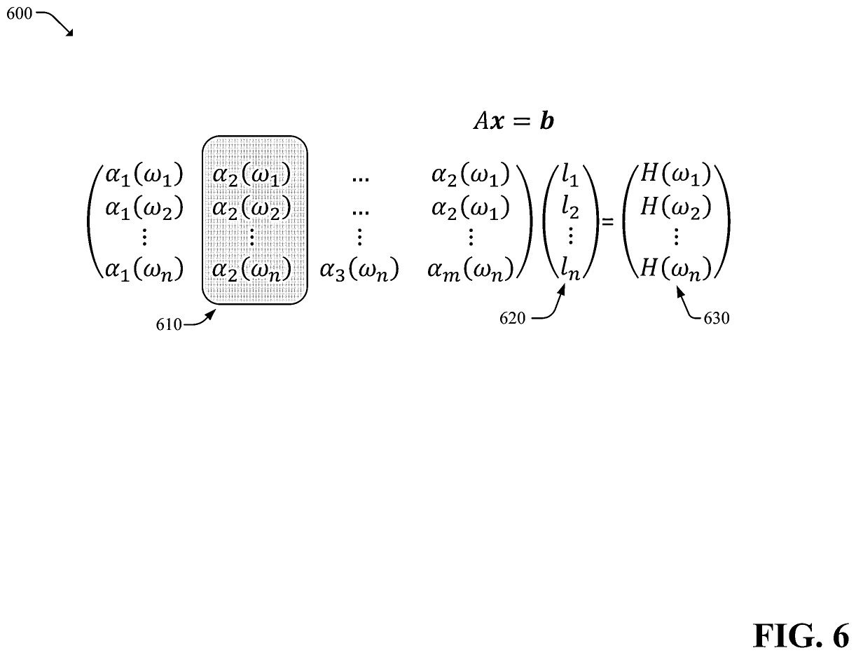

FIG. 6 illustrates an algorithm 600 for designing a plurality of absorptive layers in accordance with one or more embodiments described herein. Repetitive description of like elements and/or processes employed in respective embodiments is omitted for sake of brevity.

As shown, 610 represents column vectors of matrices showing the absorption vs frequency data of various absorptive materials with different absorptive properties, such the types of absorptive materials shown in FIG. 5. For example, the various absorptive materials may have different properties, such as different magnetic permeabilities, that provide different filter functions. 620 represents different lengths of traversal through the different absorptive materials represented in column 610. 630 is a column vector representing a described filter transfer function for a signal line (e.g., absorption vs. frequency). As the absorption at many more frequency points is known than there are types of absorptive materials, a least squares optimization can be used. For example, column 610 can be represented as the variable A, column 620 can be represented as the variable x and column 630 can be represented as the variable b, wherein Ax=b. Accordingly, the vector \hat{x} represents how much of each different type of absorptive material should be used to assemble a filter with the desired response. Therefore, by finding a solution \hat{x} that minimizes ∥Ax−b∥², a filter can be designed which provides the desired filter response.

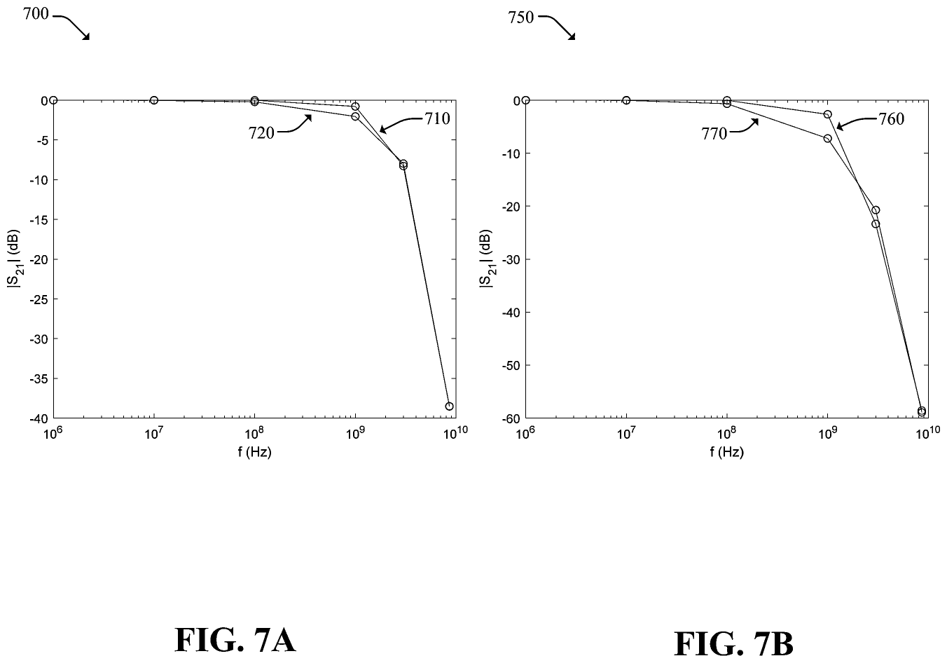

FIGS. 7A and 7B illustrate graphs 700 and 750 respectively showing the filtering of one or more filter modules in accordance with one or more embodiments described herein. Repetitive description of like elements and/or processes employed in respective embodiments is omitted for sake of brevity.

Y-axis of graphs 700 and 750 illustrate absorption (measured in dB) and the x-axis represents frequency of a signal (measured in Hz). Accordingly, graphs 700 and 750 illustrate absorption plotted as a function of frequency for a signal line traversing through filter modules designed using least square optimization as described above in relation to FIG. 7. Line 710 of graph 700 represents the filter function of a 4^{th} order Bessel Thompson 1.9 GHz cutoff. This filter function can then be used as the described filter function for algorithm 600, as described above in reference to FIG. 7. Line 720 of graph 700 represents the filter function of a filter designed using least square optimization, as described above in reference to FIG. 7, wherein the filter function of line 710 is the described filter function. The filter function represented by line 720 comprises a traversal distance of 2.13 cm of absorptive material type MF 112 and 0.611 cm of MF 117. As shown, line 720 closely approximates line 710, illustrating the effectiveness of filter modules utilizing a plurality of absorptive layers and different distances of traversal through the absorptive layers.

Line 770 of graph 750 represents the filter function of a 4^{th} order Bessel Thompson 1 GHz cutoff. This filter function can then be used as the described filter function for algorithm 600, as described above in reference to FIG. 7. Line 770 of graph 750 represents the filter function of a filter designed using least square optimization, as described above in reference to FIG. 7, wherein the filter function of line 760 is the described filter function. The filter function represented by line 870 comprises a traversal distance of 0.317 cm of absorptive material type MF 124 and 0.6 cm of MF 175. As shown, line 770 closely approximates line 760, illustrating the effectiveness of filter modules utilizing a plurality of absorptive layers and different distances of traversal through the absorptive layers.

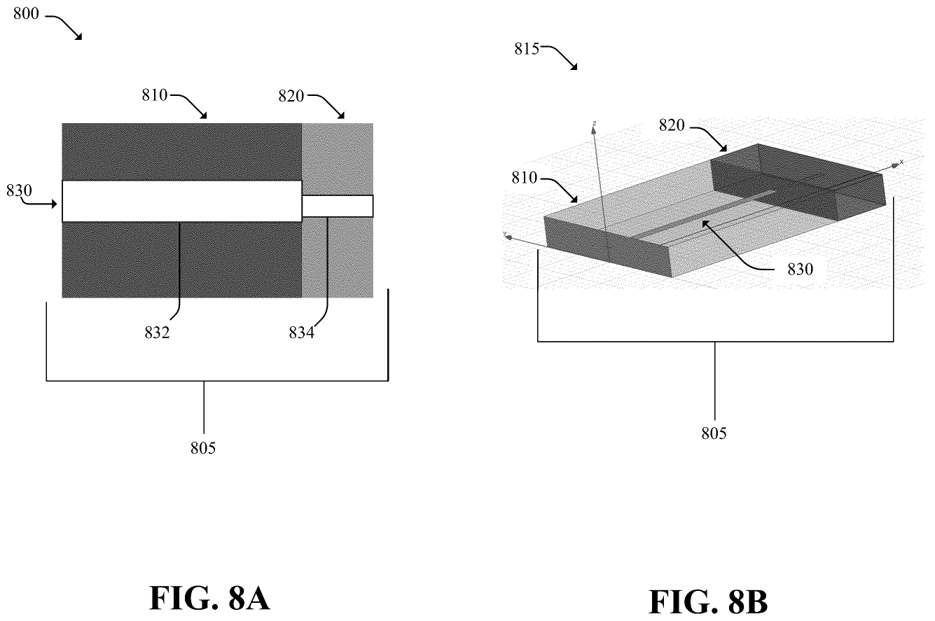

FIG. 8A illustrates a top-down view 800 of a tapered signal line in filter module 805 in accordance with one or more embodiments described herein.

In an embodiment, rather than the plurality of layers being stacked on top each other as shown in FIGS. 2-4, a plurality of absorptive materials can be placed adjacent to each other in a single layer. For example, filter module 805 can comprise a first absorptive material 810 adjacent to a second absorptive material 820. Signal line 830 can traverse through the first absorptive material 810 and the second absorptive material 820. In an embodiment, the length of the first absorptive material 810 and the length of the second absorptive material 820 can be determined using least square optimization as described above in reference to FIG. 7. In another embodiment, the width of signal line 830 can vary between various absorptive materials. For example, as shown, signal line 830 comprises a first width at point 832 in first absorptive material 810 and a second width at point 834 in second absorptive material 820. As show, the first width is greater than the second width, but it should be appreciated that any difference of width, and/or any number of changes in width between any number of absorptive materials in envisioned. In an embodiment, by tapering the width of signal line 830, impedance matching and return loss of signal 830 can be improved, thereby improving performance of a quantum computing system associated with filter module 805.

FIG. 8B illustrates an alternate view 815 of a tapered signal line in filter module 805 in accordance with one or more embodiments, described herein. Repetitive description of like elements and/or processes employed in respective embodiments is omitted for sake of brevity.

As described above in reference to FIG. 8A, in an embodiment, rather than absorptive materials being stacked in layers, as described above in reference to FIGS. 2-4, a plurality of absorptive materials can be placed adjacent to each other in a single layer. For example, as shown by view 815, first absorptive material 810 is placed adjacent to second absorptive material 820 in a single layer. In another embodiment, a layer of a plurality of layers can comprise one or more absorptive materials. For example, a layer of the plurality of layers can comprise a first absorptive material and a second absorptive material adjacent to one and other.

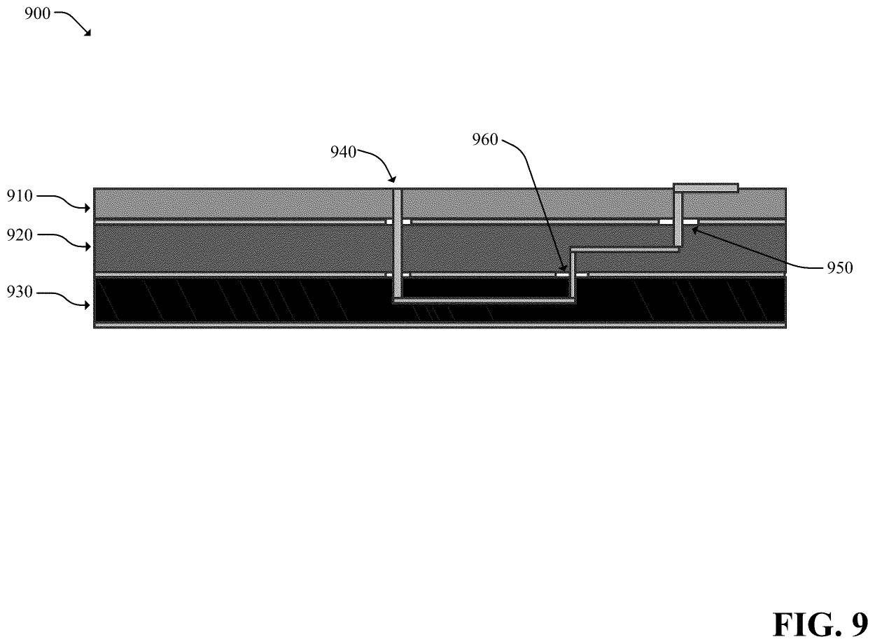

FIG. 9 illustrates a diagram of a non-limiting filtering module 900 in accordance with one or more embodiments described herein. Repetitive description of like elements and/or processes employed in respective embodiments is omitted for sake of brevity.

Filter module 900 comprises a plurality of absorptive layers (e.g., layers 910, 920 and 930) and a signal line 940 that traverses through layers 930 and 920. In an embodiment, a via can be used to connect portions of signal line 940 as signal line 940 passes between different layers. For example, via 950 connects a portion of signal line 940 which traverses through layer 920 to a portion of signal line 940 which passes through layer 910. Similarly, via 960 connects a portion of signal line 940 which traverses through layer 930 to a portion of signal line 940 which traverses through layer 920. In an embodiment, different vias can be engineered for different portions of filter module 900 to give impedance matching between layers. For example, via 950 can be engineered differently than via 960 based on the different properties of the layers the vias connect. In a further embodiment, signal line 940 can comprise one or more microstrips with different geometries, wherein the microstrips have different geometries which when combine enable different filtering properties.

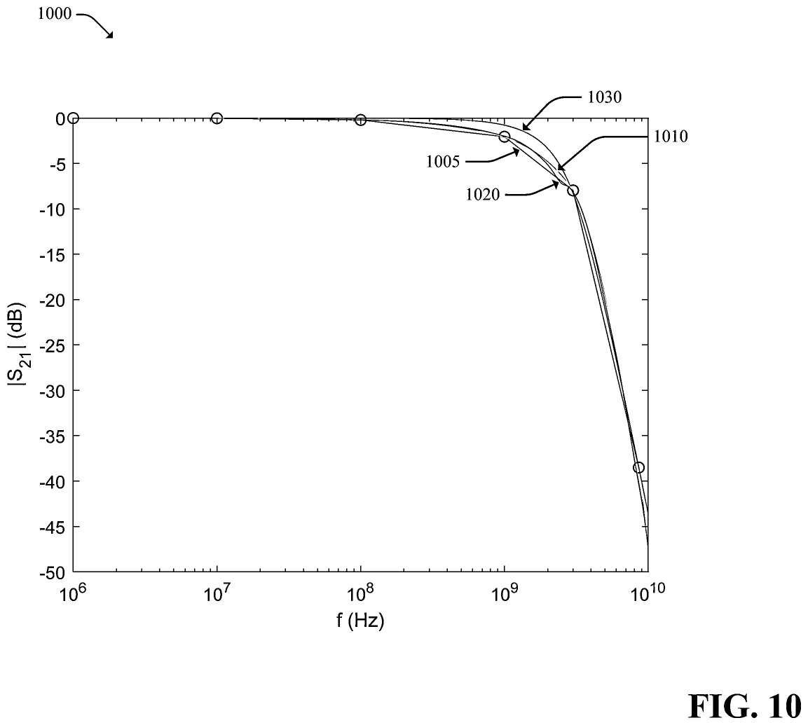

FIG. 10 illustrate graphs showing the filtering of one or more filter modules in accordance with one or more embodiments described herein. Repetitive description of like elements and/or processes employed in respective embodiments is omitted for sake of brevity.

Y-axis of graph 1000 illustrates absorption (measured in dB) and the x-axis represents frequency of a signal (measured in Hz). Accordingly, graph 1000 illustrates absorption plotted as a function of frequency for a signal line traversing through a filter module designed using least square optimization as described above in relation to FIG. 7, a filter module designed as described above in FIGS. 9A and B, and a filter module designed as described above in FIG. 10. Line 1030 of graph 1000 represents the filter function of a 4^{th} order Bessel Thompson 1.9 GHz cutoff, used in this graph as a representation of a desired filter function. Line 1005 represents the filter function of a filter designed using least square optimization as described above in reference to FIG. 7. Line 1010 represents the filter function of a filter as designed as described in FIGS. 9A and 9B. Line 1020 represents the filter function of a filter as designed as describe in FIG. 10. It should be appreciated that all of lines 1005, 1010 and 1020 approximate line 1030, illustrating the effectiveness of one or more embodiments of filter modules described herein.

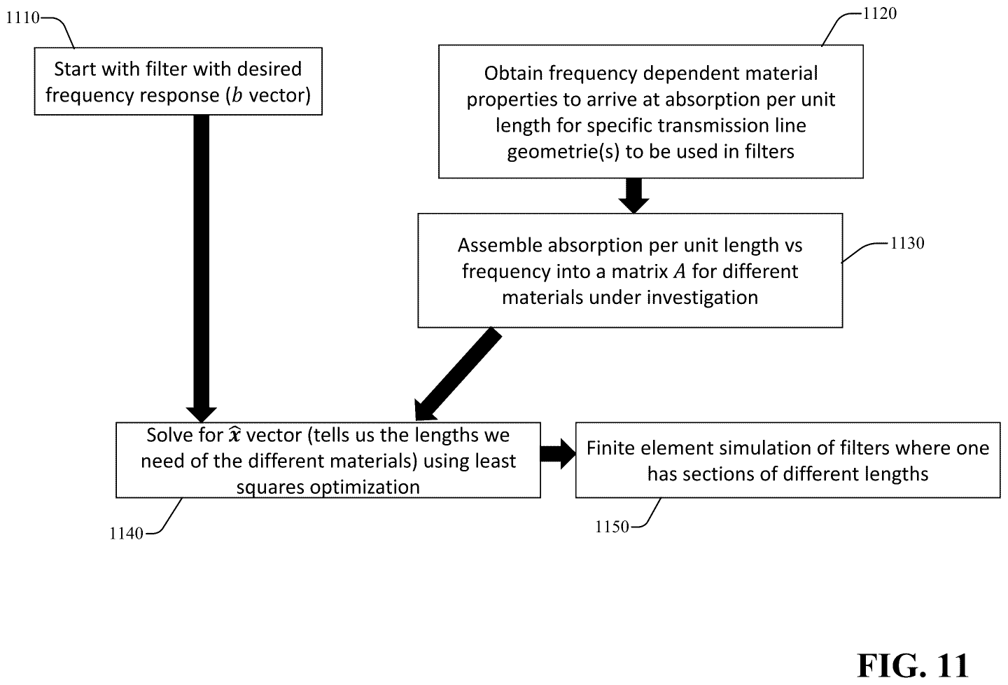

FIG. 11 illustrates a flow diagram of an example, non-limiting method for designing a filter module in accordance with one or more embodiments described herein.

At 1110, a desired frequency response for a filter (e.g., vector b) can be provided.

At 1120, the frequency dependent materials properties can be obtained to arrive at the absorption per unit length for specific transmission line geometries to be used in the filter.

At 1130, a matrix (e.g., A) can be assembled showing the absorption per unit length vs frequency for different absorptive materials being considered for use in the filter.

At 1140, lengths of different absorptive materials can be determined by using least square optimization to solve for the vector \hat{x} (e.g., the solution that minimizes ∥Ax−b∥²).

At 1150, a finite element simulation of filters where one of the absorptive layers has sections of different lengths can be performed. For example, a finite element simulation of the designed filter can be utilized to compare the filtering function of the designed filter to a desired filtering function.

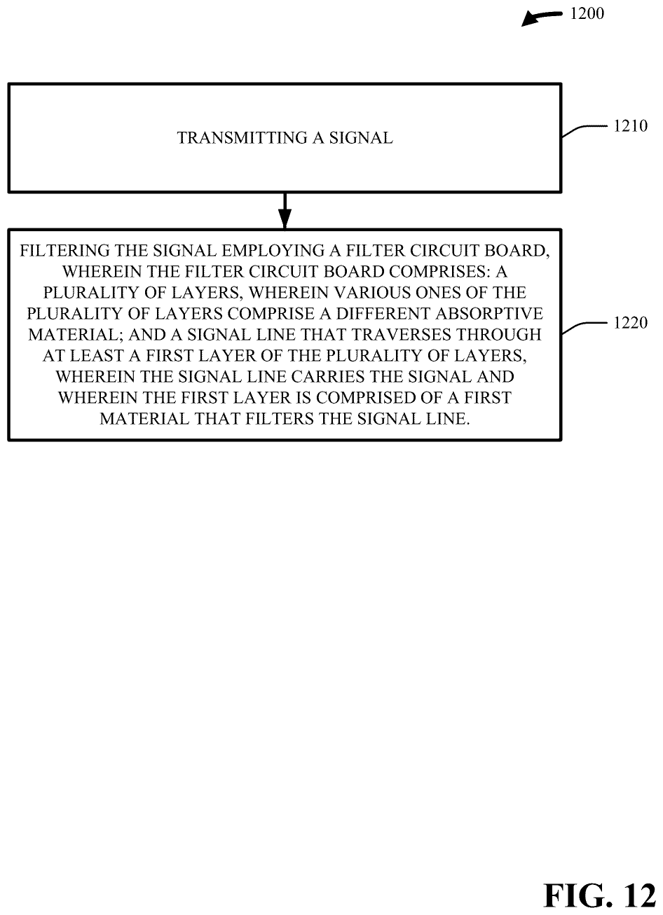

FIG. 12 illustrates a flow diagram of an example, non-limiting method 1200 of filtering an electromagnetic signal in accordance with one or more embodiments described herein. Repetitive description of like elements and/or processes employed in respective embodiments is omitted for sake of brevity.

At 1210, method 1200 can comprise transmitting a signal. For example, as described above in reference to FIGS. 2-6, the signal can comprise various signals for operation of qubits of a quantum computer such as fast flux transmission and radio frequency control signals.

At 1220, method 1200 can comprise filtering the signal employing a filter circuit board, wherein the filter circuit board comprises a plurality of layers, wherein various ones of the plurality of layers comprise a different absorptive material, and a signal line that traverses through at least a first layer of the plurality of layers, wherein the signal line carries the signal and wherein the first layer is comprised of a first material that filters the signal line. For example, as described above in reference to FIGS. 2-4, the signal line can traverse though one or more absorptive layers, wherein each absorptive layer the signal line traverses through contributes to filtering of the signal carried by the signal line. Accordingly, the one or more absorptive layers the signal line traverses through can achieve a desired filtering function that may not be possible with a single absorptive layer.

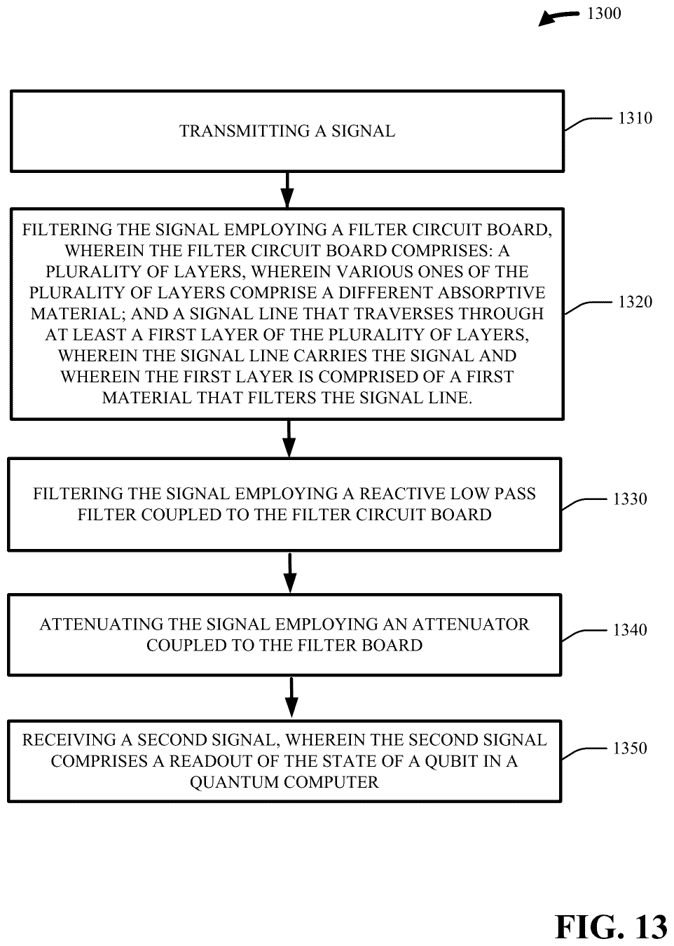

FIG. 13 illustrates a flow diagram of an example, non-limiting method 1400 of filtering a signal in accordance with one or more embodiments described herein. Repetitive description of like elements and/or processes employed in respective embodiments is omitted for sake of brevity.

At 1310, method 1300 can comprise transmitting a signal. For example, as described above in reference to FIGS. 2-6, the signal can comprise various signals for operation of qubits of a quantum computer such as fast flux transmission and radio frequency control signals. In another embodiment, the electromagnetic signal can comprise any type of signal related to operation of a qubits or quantum hardware, such as qubit control signals, readout request signals, and/or other operation signals.

At 1320, method 1300 can comprise filtering the signal employing a filter circuit board, wherein the filter circuit board comprises, a plurality of layers, wherein various ones of the plurality of layers comprise a different absorptive material, and a signal line that traverses through at least a first layer of the plurality of layers, wherein the signal line carries the signal and wherein the first layer is comprised of a first material that filters the signal line. For example, as described above in reference to FIGS. 2-4, the signal line can traverse though one or more absorptive layers, wherein each absorptive layer the signal line traverses through contributes to filtering of the signal carried by the signal line. Accordingly, the one or more absorptive layers the signal line traverses through can achieve a desired filtering function that may not be possible with a single absorptive layer.

At 1330, method 1300 can comprise filtering the signal employing a reactive low pass filter coupled to the filter circuit board. For example, as described above in reference to FIGS. 2-4, a fabricated chip comprising a reactive low pass filter can be coupled to the circuit board. In another example, the circuit board can comprise a reactive low pass filter between layers of the plurality of layers.

At 1340, method 1300 can comprise attenuating the signal employing an attenuator coupled to the filter board. For example, as described above in reference to FIGS. 2-4, a fabricated chip comprising an attenuator can be coupled to the circuit board. In another example, the circuit board can comprise an attenuator between layers of the plurality of layers.

At 1350, method 1300 can comprise receiving a second signal, wherein the second signal comprise a readout of the stat of a qubit in a quantum computer. For example, as described above in reference to FIGS. 2-4, readout signals do not call for filtering, and thus a signal line carrying the readout signal can traverse through a non-absorptive layer of the filter circuit board to prevent filtering of the readout signal.

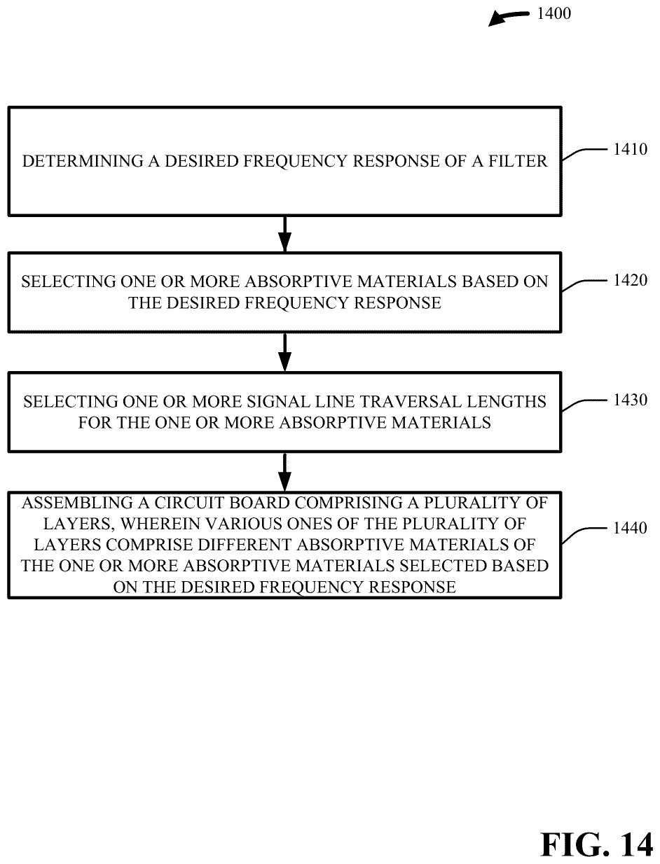

FIG. 14 illustrates a flow diagram of an example, non-limiting method 1400 for designing a filter module in accordance with one or more embodiments described herein.

At 1410, method 1400 can comprise determining a desired frequency response. For example, based on a type of signal line, a desired frequency response can be identified or provided.

At 1420, method 1400 can comprise selecting one or more absorptive materials based on the desired frequency response. For example, as described in detail above, a least square optimization method can be utilized to select one or more different absorptive materials, to achieve the desired frequency response.

At 1430, method 1400 can comprise selecting one or more signal line traversal lengths for the one or more absorptive materials. For example, as described above, a least square optimization method can be utilized to select a traversal length of a signal line through one or more absorptive materials based on the desired frequency response.

At 1440, method 1400 can comprise assembling a circuit board comprising a plurality of layers, wherein various ones of the plurality of layers comprise different absorptive materials of the one or more absorptive materials selected based on the desired frequency response.

An advantage of such methods, systems, and/or devices is that filter modules produced by such methods, systems, and/or devices enable specific filtering functions at low frequencies, wherein reactive components break down due to self-resonances. For example, filters in quantum computers, call for specific cutoff frequencies and roll-offs to minimize signal degradation. As such, a filter module as describe above can enable a desired filtering function by having a signal line traverse through one or more absorptive layers, wherein each layer the signal line traverse through, contributes to the filtering. Further, by varying the traversal distance of the signal line through an absorptive layer, differing filtering functions can be achieved. By utilizing a least square optimization, as described above, to select the various absorptive layers and signal line traversal through the various absorptive layers, a desired filtering function can be achieved that produces a desired cutoff frequency and roll-off. By achieving this desired filtering function, the filter modules described herein can reduce signal degradation, and thereby improve performance of a quantum computer by decreasing the degradation of the microwave and or radio frequency signals used to manipulate the qubits within the quantum computer.

In view of one or more embodiments described herein, a practical application of the devices described herein is decreased signal degradation in quantum computing systems. This facilitates improved performance of the quantum computing systems, and thus an improvement in the processing capacity, speed, and/or accuracy of the quantum systems.

Furthermore, one or more embodiments described herein can be employed in a real-world system based on the disclosed teachings. For example, one or more embodiments described herein can function within a system that can receive as input a quantum job request and can generate as a real-world physical pulse operated on one or more qubits of a quantum system. The output signal of one or more physical qubit devices and/or the pulse operated on the one or more qubits can be filtered by a device according to one or more embodiments described herein. The respective quantum system can generate one or more quantum results in response to the performance of the one or more physical operations on the real-world qubits of the quantum system.

It also is to be appreciated that one or more embodiments described herein can employ hardware to solve problems that are highly technical, that are not abstract, and that cannot be performed as a set of mental acts by a human. For example, a human, or even thousands of humans, cannot efficiently, accurately and/or effectively filter a signal from a quantum computer.

One or more embodiments described herein can be fully operational towards performing one or more other functions (e.g., fully powered on, fully executed and/or another function) while also performing the one or more operations described herein. It should be appreciated that such simultaneous multi-operational execution is beyond the capability of a human mind.

What is claimed is:

1. A system comprising:
a device comprising:
a circuit board comprising a plurality of layers, wherein various ones of the plurality of layers comprises a different absorptive material; and
a plurality of signal lines that pass through the circuit board, wherein a first layer of the circuit board is comprised of a first material configured to filter a first signal line that traverses through at least the first layer of the plurality of layers.

2. The system of claim 1, wherein a second layer of the circuit board is comprised of a second material configured to filter the first signal line that traverses through at least the first layer and the second layer of the plurality of layers.

3. The system of claim 2, wherein the first signal line comprises a first length that traverses through the first layer and a second length that traverses through the second layer.

4. The system of claim 1, further comprising one or more fabricated chips joined to the circuit board.

5. The system of claim 4, wherein the one or more fabricated chips comprise at least one of an attenuator or a reactive low pass filter.

6. The system of claim 1, wherein at least one layer of the plurality of layers comprises at least one of an attenuator or a reactive low pass filter.

7. The system of claim 2, wherein the first layer is formed of an absorptive material, wherein the absorptive material is configured to provide a low pass filter function, and wherein the second layer is formed of a second absorptive material, wherein the second absorptive material is configured to provide a second low pass filter function.

8. The system of claim 1, wherein a type of the first signal line is one of a microstrip or a stripline.

9. The system of claim 1, wherein one or more layers of the plurality of layers comprises a non-absorptive material.

10. A system comprising:
a device comprising:
a circuit board comprising a plurality of layers, wherein various ones of the plurality of layers comprise one or more different absorptive materials; and
a plurality of signal lines that pass through the circuit board, wherein a first layer of the circuit board is comprised of a first material and a second material, wherein a first signal line traverses through at least the first layer and wherein the first signal line comprises a first width that traverses through the first material and a second width that traverses through the second material.

11. The system of claim 10, further comprising:
a fabricated chip coupled to the first signal line.

12. The system of claim 11, wherein the fabricated chip comprises at least one of an attenuator or a reactive low pass filter.

13. The system of claim 10, wherein the first signal line traverses though at least the first layer and a second layer.

14. The system of claim 13, wherein the second layer comprises at least one of an attenuator or a reactive low pass filter.

15. The system of claim 10, further comprising:
a second fabricated chip coupled to a second signal line, wherein the second signal line traverses through at least a third layer of the plurality of layers.

16. The system of claim 15, wherein the second fabricated chip comprises at least one of an attenuator or a reactive low pass filter.

17. A method comprising:
transmitting a signal; and
filtering the signal employing a filter circuit board, wherein the filter circuit board comprises:
a plurality of layers, wherein various ones of the plurality of layers comprise a different absorptive material; and
a signal line that traverses through at least a first layer of the plurality of layers, wherein the signal line is configured to carry the signal and wherein the first layer is comprised of a first material configured to filter the signal line.

18. The method of claim 17, wherein the signal line traverses through at least the first layer and a second layer of the plurality of layers, wherein the second layer is comprised of a second material configured to filter the signal line.

19. The method of claim 17, further comprising:
filtering the signal employing a reactive low pass filter coupled to the filter circuit board.

20. The method of claim 17, further comprising:
attenuating the signal employing an attenuator coupled to the filter circuit board.

21. The method of claim 17, wherein the signal comprises a control signal for a qubit in a quantum computer.

22. The method of claim 17, wherein the signal comprises a readout request signal for a qubit in a quantum computer.

23. A system comprising:
a device comprising:
a circuit board comprising a non-absorptive layer and a plurality of absorptive layers, wherein various one of the plurality of absorptive layers comprises a different absorptive material; and
a plurality of signal lines that pass through the circuit board, wherein a first layer of the circuit board is comprised of a first material configured to filter a first signal line that travers through at least the first layer of the plurality of absorptive layers.

24. The system of claim 23, wherein a second signal line traverses through the non-absorptive layer.

25. A method comprising:
determining a desired frequency response of a filter;
selecting one or more absorptive materials based on the desired frequency response;
selecting one or more signal line traversal lengths for the one or more absorptive materials; and
assembling a circuit board comprising a plurality of layers, wherein various ones of the plurality of layers comprise different absorptive materials of the one or more absorptive materials selected based on the desired frequency response.
